(19) United States
(12) Patent Application Publication
(10) Pub. No.: US 2025/0024643 A1
(43) Pub. Date: Jan. 16, 2025

(54) THERMAL GROUND PLANE WITH VARIABLE IONIZED FLUID FLOW CONTROL FROM RESERVOIR

(71) Applicant: Intel Corporation, Santa Clara, CA (US)

(72) Inventors: Jeff Ku, Taipei (TW); Smit Kapila, Bangalore (IN); Shantanu Kulkarni, Hillsboro, OR (US); Min Suet Lim, Penang (MY); Surya Pratap Mishra, Portland, OR (US)

(21) Appl. No.: 18/897,895

(22) Filed: Sep. 26, 2024

(51) Int. Cl. H05K 7/20

(52) U.S. Cl. CPC H05K 7/20327; H05K 7/20309; H05K 7/20318; H05K 7/20381

(57) ABSTRACT

A thermal ground plane (TGP), including: a vapor chamber containing an ionized fluid; a reservoir fluidly connected with the vapor chamber, configured to store excess ionized fluid; and an electromagnetic source configured to dynamically direct a variable amount of the excess ionized fluid from the reservoir to the vapor chamber based on a thermal resistance of the ionized fluid in the vapor chamber or a temperature of the TGP at a location proximate to a heat source.

### TECHNICAL FIELD

Aspects described herein generally relate to a thermal ground plane and, more particularly, to a thermal ground plane with an electromagnetic source configured to dynamically direct a variable amount of excess ionized fluid from a reservoir.

### BACKGROUND

The performance of vapor chambers (VC) and thermal ground planes (TGP) in phase change cooling systems is influenced by the volume of water charged into the system. A higher volume of water increases the maximum heat transfer coefficient (Qmax), which is beneficial for high-power applications. However, excessive water volume can elevate the thermal resistance of the VC, leading to a higher case temperature and poorer temperature uniformity. Conversely, a lower volume of water decreases the Qmax, limiting performance under high-power conditions. There exists a critical balance where, beyond a certain input power level, the thermal resistance associated with a higher water charge becomes lower than that of a lower water charge. This balance point is challenging to identify, particularly for electronic devices operating over a wide input power range.

### BRIEF DESCRIPTION OF THE FIGURES

FIGS. 1A-1C illustrate schematic and block diagrams of a thermal ground plane in accordance with aspects of the disclosure.

FIG. 2 is a flow diagram illustrating active control of ionized fluid flow control in accordance with aspects of the disclosure.

FIG. 3 illustrates a graph depicting the thermal resistance of a TGP as a function of input power and varying amounts of ionized fluid, in accordance with aspects of the disclosure.

FIG. 4 illustrates a schematic diagram of a thermal ground plane in accordance with aspects of the disclosure.

FIG. 5 illustrates a schematic diagram of a thermal ground plane in accordance with aspects of the disclosure.

FIGS. 6A and 6B illustrate schematic diagrams of a thermal ground plane with alternative reservoir placements.

### DETAILED DESCRIPTION

The present disclosure relates to a thermal ground plane (TGP) incorporating an electromagnetic source that dynamically regulates the amount of excess ionized fluid drawn from a reservoir into a vapor chamber. By utilizing the electrical properties of the TGP, the system maintains an optimized amount of ionized fluid within the vapor chamber to accommodate varying electronic device workloads.

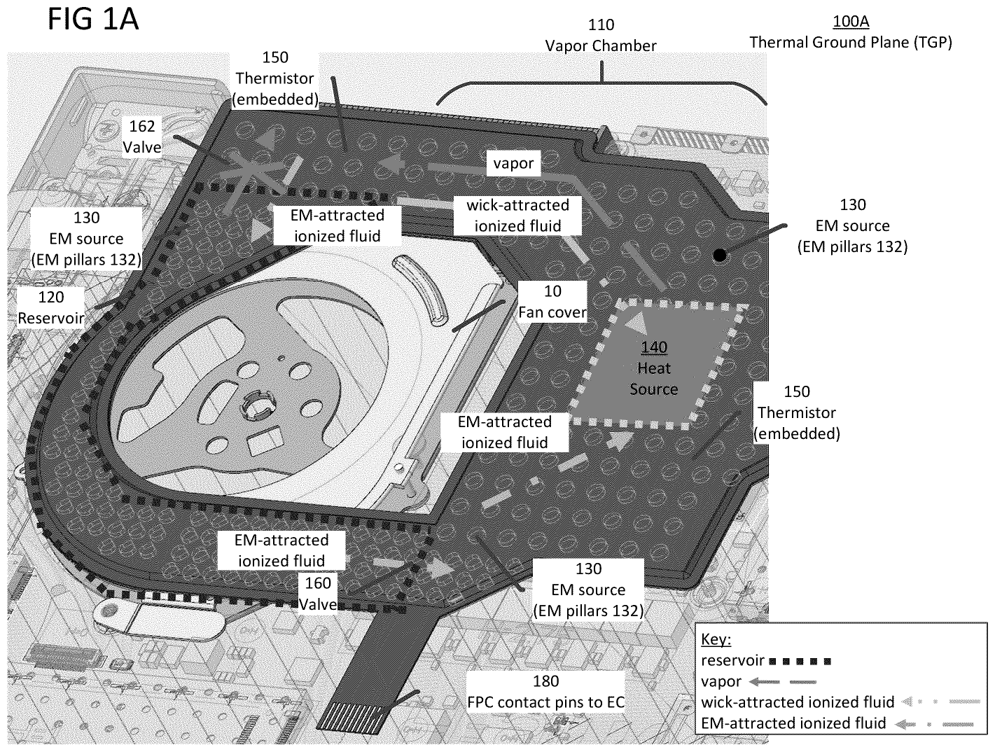

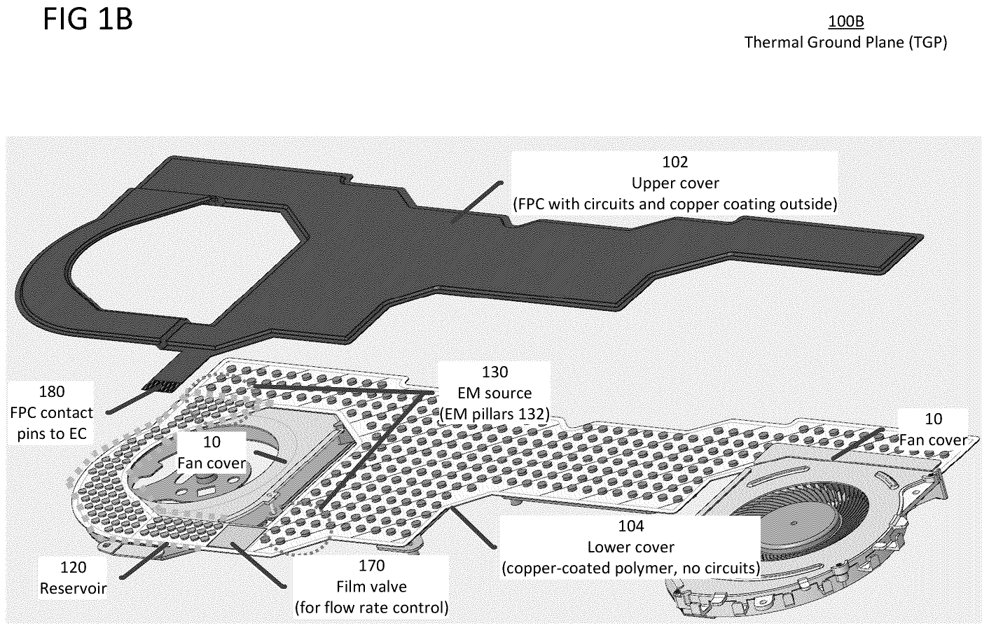

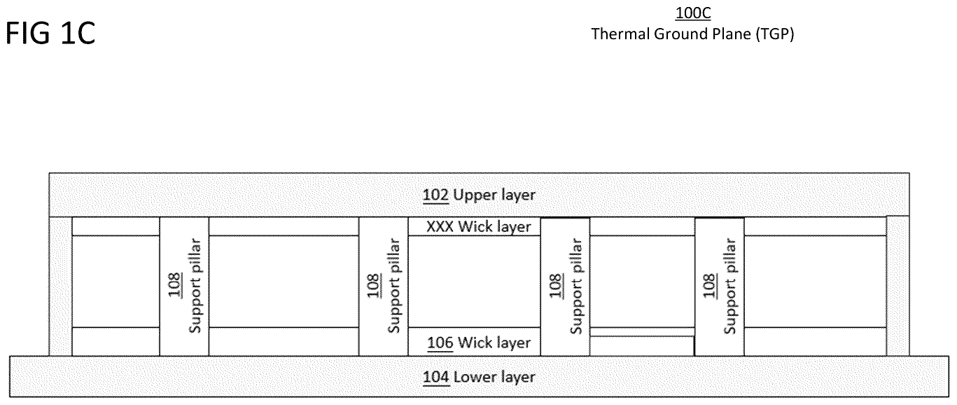

FIGS. 1A-1C illustrate schematic and block diagrams of a thermal ground plane (TGP) 100 (100A, 100B, 100C) in accordance with aspects of the disclosure.

The TGP 100 is divided into two zones: an active zone, which includes a vapor chamber 110, and a reservoir zone, which has a reservoir 120. The active zone is responsible for the evaporation and condensation of the ionized fluid, while the reservoir zone stores excess ionized fluid and dynamically controls the total amount present in the active zone. The TGP 100 features a variable liquid volume in the active area for performance optimization.

The TGP 100 comprises a vapor chamber 110, a reservoir 120, an electromagnetic source 130, one or more thermistors 150, a valve 160, a film valve 170, and flexible printed circuit (FPC) contact pins 180.

The vapor chamber 110 contains an ionized fluid, which may be ionized water or another suitable ionized fluid, selected based on the operating temperatures of the TGP 100. The vapor chamber 110 holds a mixture of ionized fluid in both liquid and vapor states within a hermetically sealed environment, and its maximum heat transfer capacity is defined as Qmax. The Qmax of the vapor chamber can vary significantly depending on factors such as heat source location, overall chamber size, and external forces like gravity.

The reservoir 120 is fluidly connected to the vapor chamber 110 and is configured to store excess ionized fluid. Ideally, the reservoir 120 is positioned on top of a fan cover 10 within an electronic device, although the aspects of the disclosure are not limited to this configuration.

The electromagnetic source 130 is configured to dynamically control the movement of excess ionized fluid from the reservoir 120 to the vapor chamber 110, based on the thermal resistance of the ionized fluid in the vapor chamber 110 and/or the temperature of the TGP 100. The electromagnetic source 130 is positioned proximate to the edge of the reservoir 120. “Proximate to” in the context of the electromagnetic source 130 refers to a position that is sufficiently close to a targeted area within the vapor chamber 110, such that the electromagnetic source 130 can effectively generate forces to control or influence the movement of the ionized fluid. The placement ensures that the electromagnetic field is strong enough to attract, repel, or guide the ionized fluid without significant loss of control due to distance or external interference.

The electromagnetic source 130 have one or more electromagnetic pillars 132 disposed between the upper layer 102 and lower layer 104 of the TGP 100. These pillars, which may be formed using standard support pillars embedded with electromagnets or electromagnetic circuits, help maintain a space between the upper layer 102 and lower layer 104. The TGP 100 may include a combination of electromagnetic pillars 132 and standard support pillars 108.

The electromagnetic source 130 is comprised of an electromagnetic material, which is a substance that interacts with or responds to electromagnetic fields, either by generating, absorbing, or influencing electric or magnetic forces, depending on its magnetic and electrical properties. The electromagnetic material may be any type of electromagnetic material appropriate for the intended purpose described in this disclosure.

The heat source 140 may comprise one or more heat-generating devices, such as a processor, logic unit, field-programmable gate array (FPGA), chip set, integrated circuit (IC), graphics processor, graphics card, battery, memory, or other similar components.

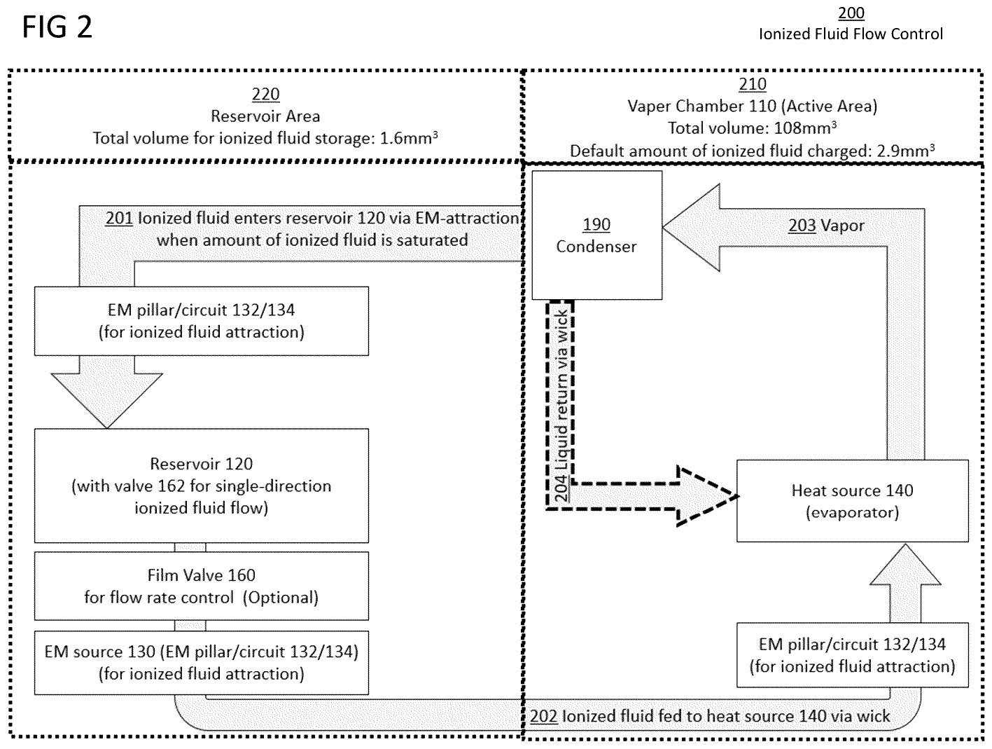

One or more thermistors 150 may be embedded in the upper layer 102 or lower layer 104 of the TGP 100. These thermistors are configured to measure the temperature of the TGP 100 at various points, including proximate to the heat source 140, reservoir 120, and condenser 190 (as shown in FIG. 2), among other possible locations. “Proximate to” in the context of thermistors 150 refers to the heat source 140, reservoir 120, and condenser 190, etc., such that the proximity ensures accurate and relevant measurement. For instance, when a thermistor 150 is placed proximate to the heat source 140 within the vapor chamber 110, it is positioned close enough to effectively sense temperature variations or changes that are directly influenced by the heat source 140.

The valve 160 (also referred to as a flow meter) is connected to the exit of the reservoir 120 and is designed to measure and/or control the flow of excess ionized fluid from the reservoir 120 to the vapor chamber 110, ensuring that fluid can exit but not re-enter the reservoir at this location. An additional valve 162 may be placed at the entrance of the reservoir 120 to allow fluid to enter but not exit the reservoir 120. The valves 160 and 162 could be, for example, Tesla valves and/or piezo valves, or any other valve that is suitable.

A film valve 170 may optionally be connected to the exit of the reservoir 120, and is designed to regulate the flow rate of the excess ionized fluid as it exits the reservoir 120.

The TGP 100 may be incorporated within an electronic device and connected to an embedded controller (EC) (not shown) via the flexible printed circuit (FPC) contact pins 180. The embedded controller is configured to generate control signals for the electromagnetic source 130 based on the thermal resistance of the ionized fluid in the vapor chamber 110 or the temperature of the TGP 100 proximate to the heat source 140. In an example implementation, the electronic device is meant to encompass a computer, a personal digital assistant (PDA), a laptop or electronic notebook, a cellular telephone, a tablet, network elements, network appliances, servers, routers, switches, gateways, bridges, load balancers, processors, modules, or any other device, component, element, or object that includes a heat source.

The embedded controller can determine whether a workload from a heat source 140 would raise the temperature of one or more heat sources 140 above a predefined threshold. In some cases, the embedded controller uses a lookup table containing data from prior conditions, parameters, workloads, and thermal responses to help assess the workload for each heat source 140 and whether it will exceed the temperature threshold. In other cases, the embedded controller can utilize other methods to make this determination. The temperature threshold may be set by the manufacturer, such as the maximum operating temperature or a value below this (e.g., 75% of the maximum operating temperature), depending on design and user preferences.

The embedded controller is also configured to generate an additional control signal to manage the valve 160, which regulates the release of excess ionized fluid based on system workload. For higher power workloads, the embedded controller adjusts the valve 160 to release a larger amount of excess ionized fluid into the vapor chamber 110 to achieve a higher Qmax. For lower power workloads, the embedded controller reduces the release of fluid to maintain a consistent temperature across the TGP 100.

The wick structure, composed of porous materials, allows the ionized fluid to flow within the vapor chamber 110. It may consist of sintered powder, metal sintered fibers, screen mesh, grooved or machined walls of the vapor chamber 110, metal foam, pins, or pillars. The wick structure enables the ionized fluid (in its condensed liquid phase) to move from cooler regions of the vapor chamber 110 to hotter areas, such as proximate to the heat source 140, through capillary action.

The wick-attracted ionized fluid moves passively through a wick structure in the vapor chamber 110, relying on capillary action to draw the ionized fluid from the condenser 190 back to the heat source 140 (the evaporator). This passive movement occurs without the need for external energy input, as the porous wick material enables the ionized fluid to naturally flow from cooler regions of the vapor chamber 110 (near the condenser 190) to the hotter regions (near the heat source 140). In contrast, the EM-attracted ionized fluid moves actively, controlled by electromagnetic forces generated by the electromagnetic source 130. These forces actively direct the ionized fluid to specific areas within the vapor chamber 110, allowing for dynamic control of fluid movement.

FIG. 2 is a flow diagram 200 illustrating active control of ionized fluid flow control in accordance with aspects of the disclosure.

The vapor chamber 110 serves as the active area 210 of the TGP 100, where heat dissipation occurs. In this example, the vapor chamber 110 holds a total ionized fluid volume of 108 mm³, with an initial charge of 2.9 mm³. The embedded controller optimizes device performance by adjusting the amount of ionized fluid in the active area 210 based on factors such as device power level, the thermal resistance of the ionized fluid, and/or the temperature of the TGP 100, particularly proximate to the heat source 140.

The reservoir 120, located in the reservoir area 220, is fluidly connected to the vapor chamber 110. In this example, the reservoir has a storage capacity of 1.6 mm³ and operates with the film valve 170 to allow single-direction flow of the ionized fluid. Dynamic control of the reservoir 120 enables the ionized fluid volume in the active area to vary between 1.3 mm³ and 4.5 mm³, keeping the TGP 100 optimized across varying device power levels.

The condenser 190, shown in FIG. 2 (but not in FIGS. 1A-1C), is fluidly connected between the heat source 140 and the reservoir 120. Its function is to condense the ionized fluid in the vapor chamber 110 from the vapor state back into the liquid state.

Ionized fluid flow control is achieved through active regulation, which directs excess ionized fluid from the condenser 190 into the reservoir 120 (Step 201). Once the excess ionized fluid enters the reservoir 120, valve 162 prevents it from flowing back to the condenser 190, trapping the fluid in the reservoir 120. The film valve 160, located at the exit of the reservoir 120, regulates the flow rate of the excess ionized fluid returning to the active area. The film valve 160 may control the outbound flow rate using a pulse width modulation (PWM) control signal from the embedded controller, in combination with the electromagnetic force generated by the electromagnetic source 130 in this region. The ionized fluid from the reservoir 120 is supplied to the heat source 140 via the wick in the vapor chamber 110 (Step 202). The electromagnetic source 130, which includes electromagnetic pillars or circuits 132/134, generates forces that attract the ionized fluid from the reservoir 120 to the vapor chamber 110, managing its movement to control fluid levels and ensure uniform temperature.

The heat source 140, also referred to as the evaporator, is the area where the liquid ionized fluid absorbs heat and transitions into the vapor state. The ionized fluid is drawn through the wick and undergoes circulation, evaporating in the process (Step 203). The condenser 190 then converts the ionized fluid back into liquid, which flows through the wick to repeat the cycle (Step 204).

Thermistors 150, placed proximate to the heat source 140 and other locations, provide real-time data on thermal resistance. The embedded controller uses this data to adjust the amount of ionized fluid in the active area, ensuring efficient thermal management.

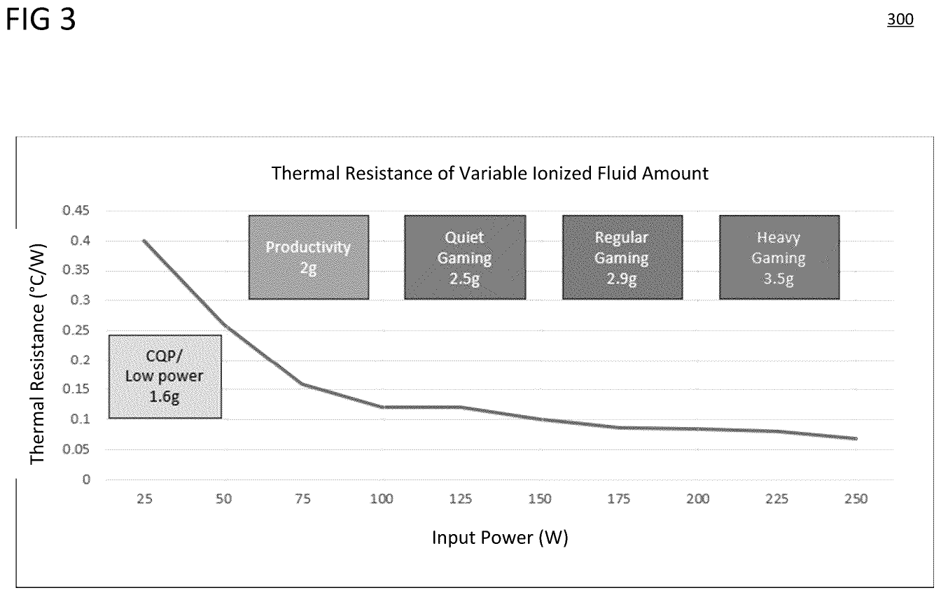

FIG. 3 illustrates a graph 300 depicting the thermal resistance of a TGP as a function of input power and varying amounts of ionized fluid, in accordance with aspects of the disclosure. Applications with heavier workloads, such as gaming, require a larger amount of ionized fluid in the vapor chamber 110 compared to lighter workloads, such as productivity applications. It is understood that graph 300 is provided for illustrative purposes only and is not intended to be limiting.

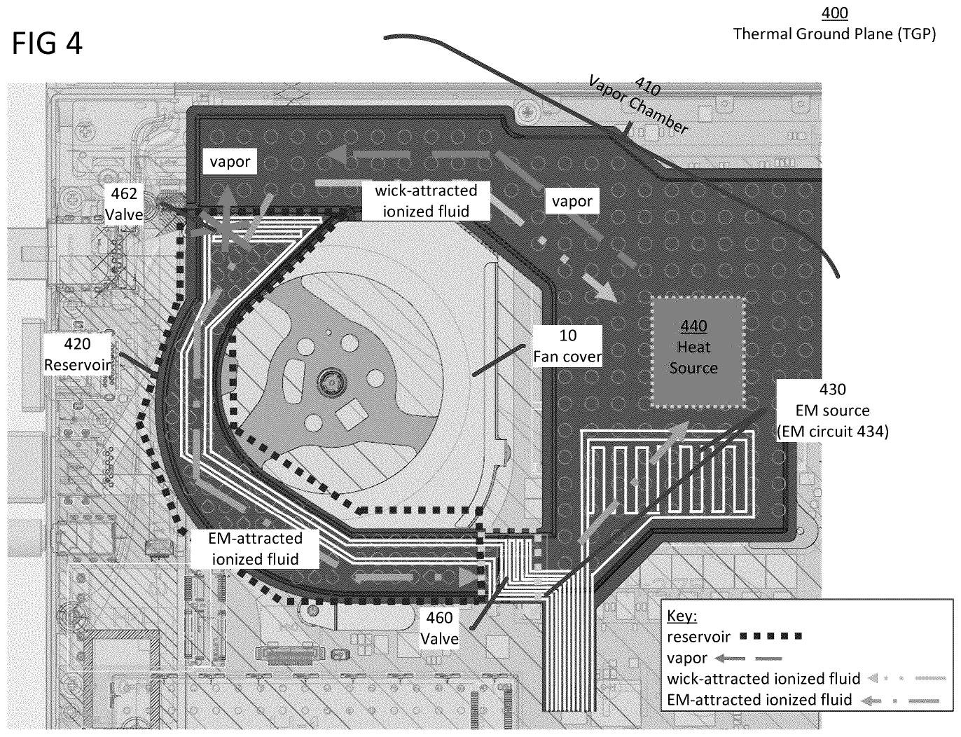

FIG. 4 illustrates a schematic diagram of a thermal ground plane (TGP) 400 in accordance with aspects of the disclosure. Similar reference numerals are used in FIG. 4 as in FIGS. 1A-1C, with the difference that the numerals in FIG. 4 begin with a “4” instead of a “1.” The descriptions of these elements are not repeated for the sake of conciseness.

Unlike the TGP 100 shown in FIGS. 1A-1C, which employs electromagnets embedded within support pillars 132, the TGP 400 utilizes circuitry to generate electromagnetic forces for controlling the movement of the ionized fluid in conjunction with valve 460. Specifically, the electromagnetic source 430 comprises one or more electromagnetic circuits 434, which are embedded within either the upper and/or lower layer of the TGP 400.

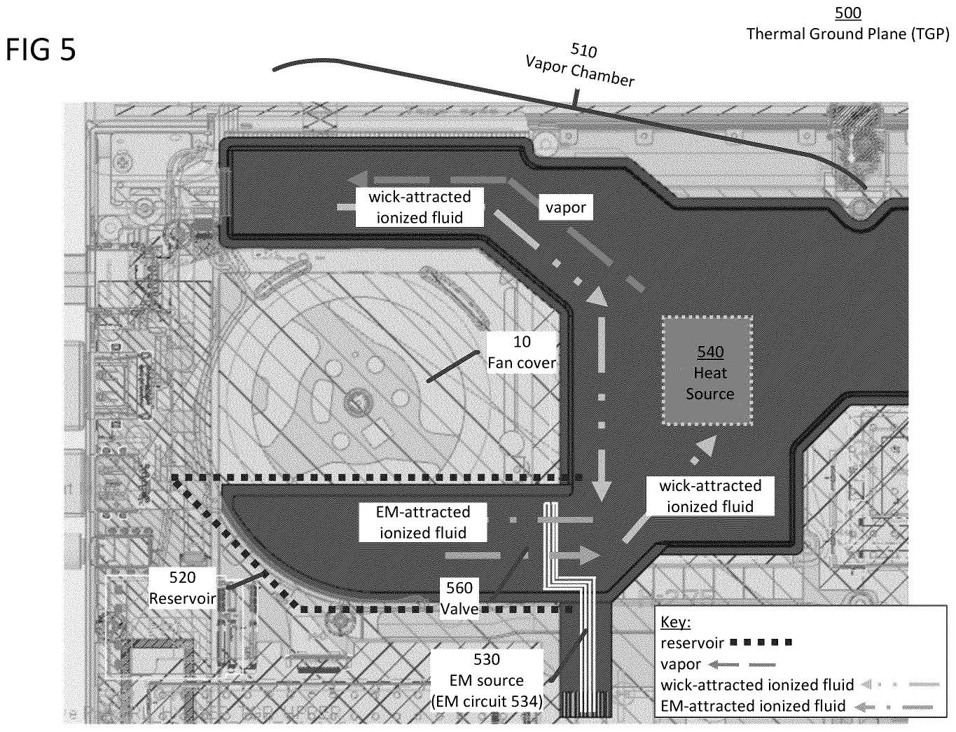

FIG. 5 illustrates a schematic diagram of a thermal ground plane 500 in accordance with aspects of the disclosure. Similar reference numerals are used in FIG. 5 as in FIGS. 1A-1C and 4, with the difference that the numerals in FIG. 5 begin with a “5.” The descriptions of these elements are not repeated for the sake of conciseness.

The reservoir 520 is formed without a loop connection to a condenser. In this configuration, a same volume of the excess ionized fluid enters and exits the reservoir 520 simultaneously.

The electromagnetic source 530 comprises one or more electromagnetic circuits 534. These one or more electromagnetic circuits 534 are embedded within the upper layer 502 or the lower layer 504 of the TGP 500.

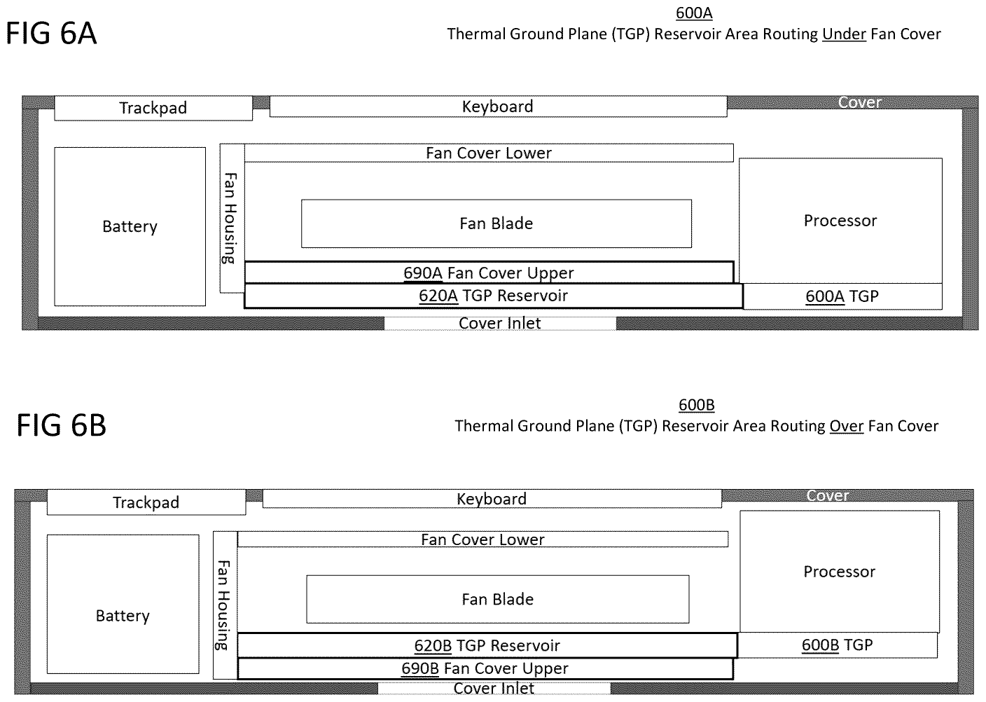

FIGS. 6A and 6B illustrate schematic diagrams of a thermal ground plane (TGP) 600 (600A and 600B), illustrating alternative placements of the reservoir 620A and 620B.

More recent TGP designs feature a thin vapor chamber produced through a printed circuit board (PCB) fabrication process. The electromagnetic source 130, 230, 430, 530 and thermistors 150 can be integrated into the PCB to dynamically control ionized fluid flow.

Leveraging this PCB capability, the TGP 600 offers flexibility in Z-height adjustments, allowing it to fit into spaces requiring a thermal solution.

For example, in FIG. 6A, the reservoir 620A is located below an upper portion of a fan cover 690A, while in FIG. 6B, the reservoir 620B is positioned above the upper portion of the fan cover 690B. The foldability of the TGP 600 allows for flexible positioning of the reservoir 620. Since the reservoir 620 does not serve as the primary heat transfer path but acts as a buffer zone for the ionized fluid, its placement can be adjusted as needed.

The techniques of this disclosure may also be described in the following examples.

Example 1. A thermal ground plane (TGP), comprising: a vapor chamber containing an ionized fluid; a reservoir fluidly connected with the vapor chamber, configured to store excess ionized fluid; and an electromagnetic source configured to dynamically direct a variable amount of the excess ionized fluid from the reservoir to the vapor chamber based on a thermal resistance of the ionized fluid in the vapor chamber or a temperature of the TGP at a location proximate to a heat source.

Example 2. The TGP of example 1, wherein the electromagnetic source is located proximate to an edge of the reservoir.

Example 3. The TGP of any one or more of examples 1-2, wherein the electromagnetic source comprises one or more electromagnetic pillars disposed between upper and lower layers of the TGP.

Example 4. The TGP of any one or more of examples 1-3, wherein the electromagnetic source comprises one or more electromagnetic circuits.

Example 5. The TGP of example 4, wherein the one or more electromagnetic circuits are embedded within support pillars disposed between upper and lower layers of the TGP.

Example 6. The TGP of example 4, wherein the one or more electromagnetic circuits are embedded within an upper or lower layer of the TGP.

Example 7. The TGP of any one or more of examples 1-6, further comprising: one or more thermistors embedded in an upper or lower layer of the TGP, configured to sense one or more temperatures of the TGP at respective locations.

Example 8. The TGP of example 7, wherein the thermistors are positioned proximate to the heat source and proximate to the reservoir.

Example 9. The TGP of example 7, further comprising: a condenser fluidly connected between the heat source and the reservoir, configured to condense the ionized fluid in the vapor chamber from vapor state to liquid state, wherein the thermistors are positioned proximate to the heat source, proximate to the reservoir, and proximate to the condenser.

Example 10. The TGP of any one or more of examples 1-9, further comprising: a valve coupled to an exit of the reservoir, configured to control a flow of the excess ionized fluid from the reservoir to the vapor chamber.

Example 11. The TGP of any one or more of examples 1-10, further comprising: a condenser fluidly connected between the heat source and the reservoir, configured to condense the ionized fluid in the vapor chamber from vapor state to liquid state.

Example 12. The TGP of any one or more of examples 1-10, wherein the reservoir is formed without a loop connection to a condenser, such that a same volume of the excess ionized fluid enters and exits the reservoir simultaneously.

Example 13. The TGP of any one or more of examples 1-12, wherein the ionized fluid is ionized water.

Example 14. The TGP of any one or more of examples 1-13, further comprising: a flow meter configured to measure a flow of the excess ionized fluid exiting the reservoir.

Example 15. An electronic device, comprising: the TGP of any one or more of examples 1-14; and an embedded controller coupled to the TGP, configured to generate a control signal to control the electromagnetic source based on the thermal resistance of the ionized fluid in the vapor chamber or the temperature of the TGP at a location proximate to the heat source.

Example 16. The electronic device of example 15, further comprising: a valve coupled to an exit of the reservoir, configured to control a flow of the excess ionized fluid from the reservoir to the vapor chamber, wherein the embedded controller is further configured to generate an additional control signal to control the valve.

Example 17. The electronic device of any one or more of examples 15-16, further comprising: a fan cover, wherein the reservoir is positioned above the fan cover.

Example 18. The electronic device of any one or more of examples 15-16, further comprising: a fan cover, wherein the reservoir is positioned below the fan cover.

Example 19. A thermal ground plane (TGP), comprising: a vapor chamber means containing an ionized fluid; a reservoir means fluidly connected with the vapor chamber, for storing excess ionized fluid; and an electromagnetic source means for dynamically directing a variable amount of the excess ionized fluid from the reservoir means to the vapor chamber means based on a thermal resistance of the ionized fluid in the vapor chamber means or a temperature of the TGP at a location proximate to a heat source.

Example 20. The TGP of example 19, wherein the electromagnetic source is located proximate to an edge of the reservoir means.

Example 21. The TGP of any one or more of examples 19-20, wherein the electromagnetic source means comprises one or more electromagnetic pillars disposed between upper and lower layers of the TGP.

Example 22. The TGP of any one or more of examples 19-21, wherein the electromagnetic source means comprises one or more electromagnetic circuits.

Example 23. The TGP of example 22, wherein the one or more electromagnetic circuits are embedded within support pillars disposed between upper and lower layers of the TGP.

Example 24. The TGP of example 22, wherein the one or more electromagnetic circuits are embedded within an upper or lower layer of the TGP.

Example 25. The TGP of any one or more of examples 19-24, further comprising: one or more thermistor means embedded in an upper or lower layer of the TGP, for sensing one or more temperatures of the TGP at respective locations.

Example 26. The TGP of example 25, wherein the thermistor means are positioned proximate to the heat source and proximate to the reservoir means.

Example 27. The TGP of example 25, further comprising: a condenser means fluidly connected between the heat source and the reservoir, for condensing the ionized fluid in the vapor chamber means from vapor state to liquid state, wherein the thermistor means are positioned proximate to the heat source, proximate to the reservoir means, and proximate to the condenser means.

Example 28. The TGP of any one or more of examples 19-27, further comprising: a valve means coupled to an exit of the reservoir means, for controlling a flow of the excess ionized fluid from the reservoir means to the vapor chamber means.

Example 29. The TGP of any one or more of examples 19-28, further comprising: a condenser means fluidly connected between the heat source and the reservoir, for condensing the ionized fluid in the vapor chamber from vapor state to liquid state.

Example 30. The TGP of any one or more of examples 19-28, wherein the reservoir means is formed without a loop connection to a condenser means, such that a same volume of the excess ionized fluid enters and exits the reservoir means simultaneously.

Example 31. The TGP of any one or more of examples 19-30, wherein the ionized fluid is ionized water.

Example 32. The TGP of any one or more of examples 19-31, further comprising: a flow meter means for measuring a flow of the excess ionized fluid exiting the reservoir.

Example 33. An electronic device, comprising: the TGP of any one or more of examples 19-32; and an embedded controller means coupled to the TGP, for generating a control signal to control the electromagnetic source means based on the thermal resistance of the ionized fluid in the vapor chamber means or the temperature of the TGP at a location proximate to the heat source.

Example 34. The electronic device of example 33, further comprising: a valve means coupled to an exit of the reservoir means, for controlling a flow of the excess ionized fluid from the reservoir means to the vapor chamber means, wherein the embedded controller means is further for generating an additional control signal to control the valve means.

Example 35. The electronic device of any one or more of examples 33-34, further comprising: a fan cover, wherein the reservoir means is positioned above the fan cover.

Example 36. The electronic device of any one or more of examples 33-34, further comprising: a fan cover, wherein the reservoir means is positioned below the fan cover.

While the foregoing has been described in conjunction with exemplary aspect, it is understood that the term “exemplary” is merely meant as an example, rather than the best or optimal. Accordingly, the disclosure is intended to cover alternatives, modifications and equivalents, which may be included within the scope of the disclosure.

Although specific aspects have been illustrated and described herein, it will be appreciated by those of ordinary skill in the art that a variety of alternate and/or equivalent implementations may be substituted for the specific aspects shown and described without departing from the scope of the present application. This application is intended to cover any adaptations or variations of the specific aspects discussed herein.

1. A thermal ground plane (TGP), comprising:
a vapor chamber containing an ionized fluid;
a reservoir fluidly connected with the vapor chamber, configured to store excess ionized fluid; and
an electromagnetic source configured to dynamically direct a variable amount of the excess ionized fluid from the reservoir to the vapor chamber based on a thermal resistance of the ionized fluid in the vapor chamber or a temperature of the TGP at a location proximate to a heat source.

2. The TGP of claim 1, wherein the electromagnetic source is located proximate to an edge of the reservoir.

3. The TGP of claim 1, wherein the electromagnetic source comprises one or more electromagnetic pillars disposed between upper and lower layers of the TGP.

4. The TGP of claim 1, wherein the electromagnetic source comprises one or more electromagnetic circuits.

5. The TGP of claim 4, wherein the one or more electromagnetic circuits are embedded within support pillars disposed between upper and lower layers of the TGP.

6. The TGP of claim 4, wherein the one or more electromagnetic circuits are embedded within an upper or lower layer of the TGP.

7. The TGP of claim 1, further comprising:
one or more thermistors embedded in an upper or lower layer of the TGP, configured to sense one or more temperatures of the TGP at respective locations.

8. The TGP of claim 7, wherein the thermistors are positioned proximate to the heat source and proximate to the reservoir.

9. The TGP of claim 7, further comprising:
a condenser fluidly connected between the heat source and the reservoir, configured to condense the ionized fluid in the vapor chamber from vapor state to liquid state,
wherein the thermistors are positioned proximate to the heat source, proximate to the reservoir, and proximate to the condenser.

10. The TGP of claim 1, further comprising:
a valve coupled to an exit of the reservoir, configured to control a flow of the excess ionized fluid from the reservoir to the vapor chamber.

11. The TGP of claim 1, further comprising:
a condenser fluidly connected between the heat source and the reservoir, configured to condense the ionized fluid in the vapor chamber from vapor state to liquid state.

12. The TGP of claim 1, wherein the reservoir is formed without a loop connection to a condenser, such that a same volume of the excess ionized fluid enters and exits the reservoir simultaneously.

13. The TGP of claim 1, wherein the ionized fluid is ionized water.

14. The TGP of claim 1, further comprising:
a flow meter configured to measure a flow of the excess ionized fluid exiting the reservoir.

15. An electronic device, comprising:
the TGP of claim 1; and
an embedded controller coupled to the TGP, configured to generate a control signal to control the electromagnetic source based on the thermal resistance of the ionized fluid in the vapor chamber or the temperature of the TGP at a location proximate to the heat source.

16. The electronic device of claim 15, further comprising:
a valve coupled to an exit of the reservoir, configured to control a flow of the excess ionized fluid from the reservoir to the vapor chamber,
wherein the embedded controller is further configured to generate an additional control signal to control the valve.

17. The electronic device of claim 15, further comprising:
a fan cover,
wherein the reservoir is positioned above the fan cover.

18. The electronic device of claim 15, further comprising:
a fan cover,
wherein the reservoir is positioned below the fan cover.
